(19) United States
(12) Patent Application Publication
(10) Pub. No.: US 2025/0377420 A1
(43) Pub. Date: Dec. 11, 2025

(54) ELECTROMAGNETIC MAGNETIC SENSOR ASSEMBLY

(71) Applicant: Applied Materials, Inc., Santa Clara, CA (US)

(72) Inventors: Erich NEUMANN, Dresden (DE); Thorsten MEISS, Darmstadt (DE)

(21) Appl. No.: 18/782,761

(22) Filed: Jul. 24, 2024

Related U.S. Application Data
(60) Provisional application No. 63/656,980, filed on Jun. 6, 2024.

(51) Int. Cl. G01R 33/09; G01R 33/00; G01R 33/24

(52) U.S. Cl. CPC G01R 33/091; G01R 33/0017; G01R 33/24

(57) ABSTRACT

A magnetic sensor includes a base including a first side and a second side; a current source; at least one coil coupled to the base and coupled to the current source, wherein a magnetic flux is generated when the current source supplies a current to the at least one coil; and a first sensor element and a second sensor element coupled to the base, wherein the first sensor element and second sensor element are configured to measure magnetic flux density, and the generated magnetic flux is configured to pass through the first sensor element in a first direction and pass through the second sensor element in a second direction that is opposite to the first direction.

### CROSS-REFERENCE TO RELATED APPLICATIONS

This application claims priority to and the benefit of U.S. Provisional Application No. 63/656,980 entitled “An Electromagnetic Magnetic Sensor Assembly” filed on Jun. 6, 2024. The aforementioned application is incorporated by reference herein.

### BACKGROUND

### Field

Embodiments of the present disclosure generally relate to a magnetic sensor for detecting a position of a magnetically levitated carrier.

### Description of the Related Art

Semiconductor devices are typically formed on semiconductor substrates using processing systems which include several process chambers, where each process chamber is used to complete one or more of the various steps (e.g., depositions) to form the semiconductor devices (e.g., a memory chip). Processing systems may use substrate transfer systems to move substrates between each of the process chambers. The process chambers and the substrate transfer system of the processing system may each be held at vacuum during processing. Substrate transfer systems may utilize a magnetically levitated carrier to move the substrates through and between each of the process chambers. However, precise, reliable, and smooth transportation of the carriers into and out of each of the process chambers during the various steps used to form semiconductor devices may be challenging. Conventional magnetic sensors generate magnetic fields that interfere with the ability of the substrate transfer system to levitate and convey the carrier. Additionally, conventional magnetic sensors can adversely impact a process occurring the process chamber, such as affecting the process plasma used to form the semiconductor device.

Accordingly, there exists in the art a need for an improved magnetic sensor to detect a position of a magnetically levitated carrier without adversely impacting the ability of the substrate transfer system to levitate and convey substrates disposed within the carrier and without impacting semiconductor fabrication processes.

### SUMMARY

A magnetic sensor includes a base including a first side and a second side; a current source; at least one coil coupled to the base and coupled to the current source, wherein a magnetic flux is generated when the current source supplies a current to the at least one coil; and a first sensor element and a second sensor element coupled to the base, wherein the first sensor element and second sensor element are configured to measure magnetic flux density, and the generated magnetic flux is configured to pass through the first sensor element in a first direction and pass through the second sensor element in a second direction that is opposite to the first direction.

A magnetic levitation actuator assembly includes a linear stator a magnetic sensor positioned adjacent to the linear stator, wherein the magnetic sensor comprises: a base; an electromagnet including at least one coil configured to generate a magnetic flux, the at least one coil coupled to the base; and a first sensor element and a second sensor element coupled to the base, wherein: the first sensor element and second sensor element are configured to measure magnetic flux density, and the magnetic flux generated by the at least one electromagnet is configured to pass through the first sensor element in a first direction and pass through the second sensor element in a second direction that is opposite to the first direction.

A method of monitoring a carrier within a station, comprising: supplying a first current to a first electromagnet of one more first sensors of an first array of sensors disposed in a first axial direction above a membrane disposed within a station, and detecting, by use of a first sensor, a first magnetic field strength generated by the first electromagnet, wherein the first magnetic field strength varies as a size of a gap formed between the membrane and a carrier disposed in a first position underneath the membrane varies; moving the carrier levitated below the membrane to a second position along the first direction; reducing the first current to first electromagnet; and supplying a second current to a second electromagnet of one more second sensors of an second array of sensor disposed in a second axial direction above the membrane, detecting, by use of a second sensor, a second magnetic field strength generated by the second electromagnet, wherein the second magnetic field strength varies as a size of the gap formed between the membrane and the carrier disposed in the second position underneath the membrane varies.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 illustrates a top schematic view of an example substrate processing system, in which embodiments of the present disclosure may be implemented.

FIG. 2A illustrates a side view of a portion of an example station of the substrate processing system of FIG. 1, in which embodiments of the present disclosure may be implemented.

FIG. 2B illustrates a side view of a portion of an example station of the substrate processing system of FIG. 1, in which embodiments of the present disclosure may be implemented.

FIG. 2C illustrates a schematic partial cross-sectional view of the portion shown in FIG. 2B, in which embodiments of the present disclosure may be implemented.

FIG. 3 illustrates an example carrier that includes a base and a magnetic levitation elements, in accordance with embodiments of the present disclosure.

FIG. 4A illustrates a partial cross-sectional view of a portion of an example station showing an exemplary magnetic sensor, in accordance with embodiments of the present disclosure.

FIG. 4B illustrates a partial cross-sectional view of a portion of an example station showing an exemplary magnetic sensor, in accordance with embodiments of the present disclosure.

FIG. 5A illustrates a partial cross-sectional view of a portion of an example process station that includes an exemplary magnetic sensor, in accordance with embodiments of the present disclosure.

FIG. 5B illustrates a graph illustrating an alternating current supplied by an AC current source of the exemplary magnetic sensor shown in FIG. 5A, in accordance with embodiments of the present disclosure.

FIG. 5C illustrates a graph of a voltage signal output by the exemplary magnetic sensor shown in FIG. 5A, in accordance with embodiments of the present disclosure.

FIG. 6 illustrates a top view of a system that includes the example carrier of FIG. 3 and an example routing station, in accordance with embodiments of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to magnetic sensors that are compatible with a substrate transfer systems, including the use of one or more magnetic sensors to detect the position of a carrier configured to support and transfer objects. In some embodiments, the magnetic sensors detect the position of the carrier through a solid magnetically permeable membrane that is disposed between the carrier and the magnetic sensor. The magnetic sensor may have one or more electromagnets that generate a useable magnetic field that passes through the sensor elements. The electromagnets are connected to a current source to provide a magnetic field with a consistent and controllable magnetic field strength. In some embodiments, the electromagnet is coupled to a direct current (DC) current source. In some embodiments, the electromagnet is coupled to an alternating current (AC) source. These magnetic sensors with one or more electromagnets can be effectively used in high temperature environments to detect the position of the carrier.

Additionally, the electromagnets of the magnetic sensors can be selectively switched off when desired. For example, one or more of the magnetic sensors of a plurality of magnetic sensors may be switched off to manage the attraction force experienced by the carrier due to the magnetic field generated by the electromagnet in the magnetic sensor. As another example, the plurality of magnetic sensors may be switched off to allow delicate semiconductor fabrication processes, such as plasma processes, to occur within the process station without interference from the magnetic field of the plurality of magnetic sensors.

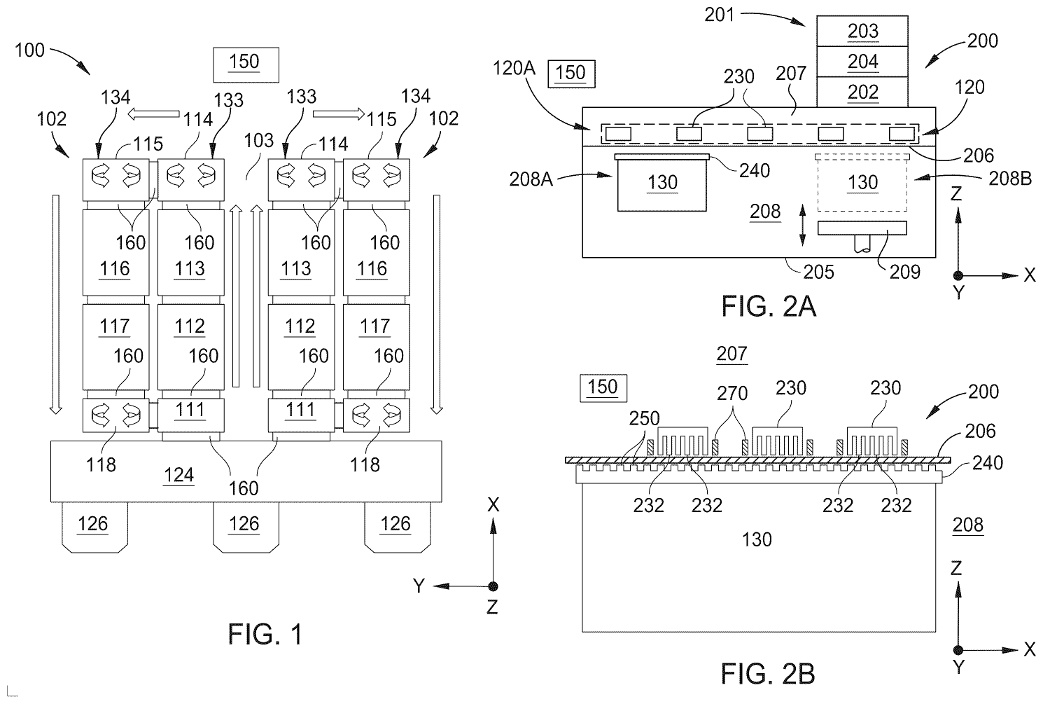

FIG. 1 illustrates a top schematic view of an example substrate processing system 100, in which embodiments of the present disclosure may be implemented. The substrate processing system 100 includes a controller 150 and one or more processing lines 102.

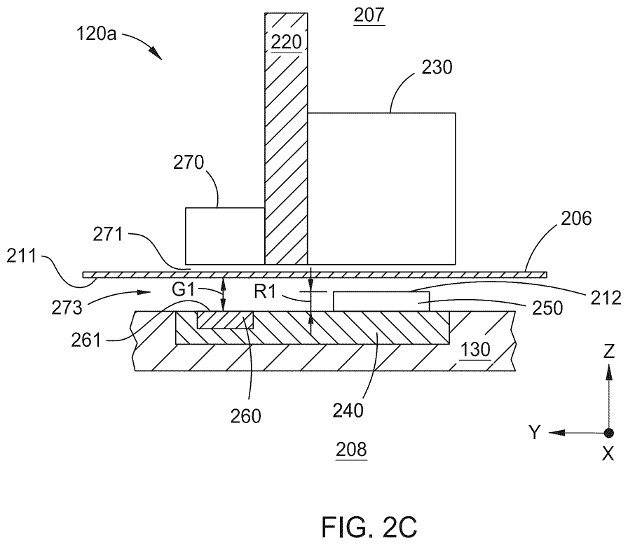

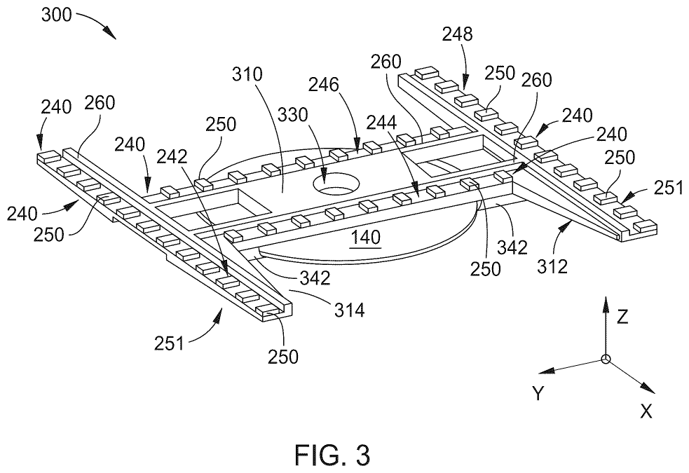

The one or more processing lines 102 each include a plurality of stations. In one example, the processing line 102 illustrated on the right side of FIG. 1 includes at least four process stations 112, 113, 116, and 117, the processing line 102 illustrated on the left side of FIG. 1 includes at least four process stations 112, 113, 116, and 117. However, process stations 111, 114, and 115 may also be configured to perform one or more substrate processing processes. Each processing line 102 may include a magnetic transportation system (not shown) that include a plurality of individual magnetic levitation assemblies disposed within the stations 111-118 that are configured to convey an object 140 (FIG. 3) disposed on a carrier 130 (FIGS. 2A-2B, and exemplary carrier 300 shown in FIG. 3) through the processing line 102. Each processing line 102 may be independent of other processing lines 102. The processing lines 102 may be physically separated by one another by a gap 103. The gap 103 may be sized such that a technician may walk between each processing line 102 to service the one or more stations 111-118.

Each processing line 102 may include a plurality of slit valves 160 to selectively isolate each station 111-118. The slit valves 160 may be selectively opened and closed to allow a clear path for the travel of the carrier 130, to selectively isolate the stations 111-118 from one another, and to facilitate the pressurization or depressurization of the stations 111-118.

The substrate processing system 100 may be used to process multiple substrates in each processing line 102 to produce a desired fabricated substrate. In some cases, the substrate processing system 100 may include a plurality of physical vapor deposition (PVD) processing chambers. For example, the first station 111 may be a first load lock station, the second station 112 may be a degas station, the third station 113 may be a pre-clean station, the fourth station 114 may be a routing station, the fifth station 115 may be a routing station, the sixth station 116 may be a PVD tantalum nitride deposition station, the seventh station 117 may be a PVD copper deposition station, and the eighth station 118 may be a routing station that also serves as a buffer station. An object 140 (e.g., substrate) may be transferred and processed within each process station 112-113 and 116-117. The pressure within each station 111-118 may decrease from station to station. For example, the pressure within the seventh station 117 may be the lower than the pressure within the other stations (e.g., stations 111-116 and 118).

The first station 111 (e.g., load lock station) may have a magnetic levitation assembly 120 (shown in FIG. 2A), which includes one or more magnetic levitation actuator assemblies 120A that include a plurality of linear stators 230 (FIG. 2B) and a plurality of sensors 270. Each magnetic levitation actuator assembly 120A may include the plurality of linear stators 230 arranged in a linear array (e.g., row) and the plurality of sensors 270 arranged in a linear array adjacent to the linear array of linear stators 230. The carrier 130 is conveyed along the linear array of linear stators 230. As will be discussed further below, the stations 111-118 will each typically include two or more magnetic levitation actuator assemblies 120A that are spaced apart within each of the stations 111-118 to support the carrier 130 as the carrier 130 is transferred through the station. The stations 112-113 and 116-117 (e.g., process stations) may each have a magnetic levitation assembly 120. The fourth station 114, fifth station 115, and eighth station 118 (e.g., routing stations) may each have a magnetic levitation assembly 120. The fifth station 115 may also include a plurality of shutter disks to be placed on a carrier 130 without the object 140. The shutter disks are used to receive deposition material when needed in the place of the object 140 to clean processing equipment, such as cleaning buildup found on a PVD target disposed within the PVD deposition process stations (e.g., stations 116-117).

The magnetic levitation assembly 120 of the first station 111 and the magnetic levitation assembly 120 of the eighth station 118 may cooperate to change the transfer direction (e.g., X-direction to Y-direction) of the carrier 130 within the substrate processing system 100. Additionally, the magnetic levitation assembly 120 of the fourth station 114 and the magnetic levitation assembly 120 of the fifth station 115 may cooperate to change the transfer direction of travel of the carrier 130.

FIGS. 1, 2A, 2B, 2C, and 3-6 include an X-Y-Z coordinate system to illustrate the transfer directions of the carrier 130 and object 140 through the substrate processing system 100, as well as the orientation of the carrier (e.g., carrier 130, 300). The arrows illustrate the direction that one or more carriers 130 circulate within the processing line 102. During an example processing operation, the carrier 130 receives an object 140 (see FIG. 3 showing carrier 300) entering the first station 111 in the X-direction from one or more front opening unified pods (FOUPS) 126 of a factory interface 124. The carrier 130 is then conveyed to the second station 112 in the X-direction. The first station 111 also receives the carrier 130 from the eighth station 118 in the Y-direction. After the carrier 130 is conveyed into the second station 112, the carrier 130 is conveyed to the fourth station 114 through the third station 113 in the X-direction. The carrier 130 is then conveyed from the fourth station 114 to the fifth station 115 in the Y-direction. The carrier 130 is then conveyed from the fifth station 115 to the eighth station 118 in the negative X-direction through the stations 116-117. The carrier 130 is then conveyed in the Y-direction back into the first station 111. The now fabricated object 140 is transferred back to the FOUP 126. Another object 140 may then be placed onto the carrier 130 in the first station 111 for another processing operation. A shutter disk may be conveyed on a carrier 130 from the fifth station 115 to the first station 111 in a similar manner as the object 140.

In some embodiments of the substrate processing system 100, the processing line 102 has a non-deposition portion 133 and a deposition portion 134. The non-deposition portion 133 may include a linear arrangement of stations, such as the first station 111, the second station 112, the third station 113, and the fourth station 114, that do not subject the object 140 to a process that deposits a layer on the object 140. After the object 140 passes through the non-deposition portion 133, the object 140 is conveyed into the deposition portion 134 that may be a linear arrangement of stations, such as the fifth station 115, the sixth station 116, the seventh station 117, and the eighth station 118, that includes at least one station that deposits at least one layer the object. For example, the non-deposition portion 133 includes the first station 111 that is a first load lock, the second station 112 that is a degas station, the third station 113 that is a pre-clean station, and the fourth station 114 that is a routing station. The deposition portion 134 includes the fifth station 115 that is a routing station, the sixth station 116 that is a tantalum nitride deposition station, the seventh station 117 that is a copper deposition station, and the eighth station 118 that is a routing station that also serves as a buffer station.

FIG. 2A and FIG. 2B each illustrate side views of a portion 200 of an example process station (e.g., stations 112-113 and 116-117) of the substrate processing system 100 of FIG. 1, in which embodiments of the present disclosure may be implemented. The example process station, which may be the process station 112-113, 116-117 described above, may be referred to herein as simply the process station 205 for clarity. The process station 205 may be configured for contactless transportation of the carrier 130. The process station 205 may include a process chamber 201 that is maintained at a vacuum pressure, such that a processing region 204 of the process chamber 201 is at a pressure that is less than 760 Torr, or even at a pressure between 1 milliTorr (mTorr) and 500 Torr. The process station 205 may be configured for contactless transportation of the carrier 130 in a vacuum chamber (see second region 208) disposed below the processing chamber.

The process station 205 includes a membrane 206 (FIGS. 2B-2C) disposed between the carrier 130 and the magnetic levitation assembly 120. The pressure may be different on opposing sides of the membrane 206. For example, the membrane 206 may be a barrier that isolates a first region 207 of the process station 205 that includes the magnetic levitation assembly 120 from a second region 208 (e.g., vacuum chamber, transport region) where the carrier 130 is located. The first region 207 may be at atmospheric pressure while the second region 208 may be at a vacuum pressure.

The membrane 206 may be made from a material selected from a group comprising transition metals (e.g., iron, nickel, cobalt) and their alloys, and alloys of rare-earth metals. In some embodiments, the membrane 206 is formed from a non-ferromagnetic material, such as some found in metallic and ceramic materials. In one example, the membrane 206 may be formed from a stainless steel, such as a non-ferromagnetic stainless steel (e.g., 301, T304, 304, 316). In some embodiments, the membrane is formed from a titanium alloy. In another example, the membrane is formed from a ceramic material, such e.g., alumina, quartz, zirconia, etc. Thus, the membrane 206 may be made of a non-transparent material in some embodiments that blocks the line of sight between the sensor 270 and the carrier 130.

The carrier 130 may be configured to carry one or more objects 140. For example, the carrier 130 may be a substrate carrier, a shutter disk carrier or a mask carrier. The carrier 130 may also be configured to transport process kit component parts. The carrier 130 may be transported in the X-direction or negative X-direction, as illustrated in FIG. 2A. The carrier 130 may also be transported in the Y-direction or negative Y-direction, as described above.

The carrier 130 includes one or more a magnetic levitation elements 240 that allow the carrier 130 to be levitated and transported through the process station 205. The magnetic levitation element 240 may be a track in the X-direction or the Y-direction. The magnetic levitation element 240 may be a substantially straight magnetic levitation element 240, or may at least include one or more straight portions that allow the carrier 130 to be contactlessly transported through the substrate processing system 100. The magnetic levitation element 240 may define a transportation direction (or transport direction), along which the carrier 130 is contactlessly transported. In one example, as illustrated in FIG. 2A, the carrier 130, which includes one or more magnetic levitation elements 240, is transferred through the process station 205, and to and from other adjacent process stations 205 (not shown), by magnetic levitation, without the carrier 130 contacting the walls or components within the process station 205.

As illustrated in FIG. 2A, the process station 205 includes a magnetic levitation assembly 120 that includes a plurality of magnetic levitation actuator assemblies 120A. The magnetic levitation actuator assemblies 120A interact with a corresponding magnetic levitation element 240 through the membrane 206. The magnetic levitation actuator assemblies 120A each include a plurality of linear stators 230. For example, a magnetic levitation actuator assembly 120A may include two or more, three or more, five or more, or 10 or more linear stators 230, depending on the desired length of the magnetic levitation elements 240, which is often referred to herein as a magnetic levitation element 240. Alternatively, the magnetic levitation actuator assemblies 120A of the magnetic levitation assembly 120 may include one elongated linear stator 230 extending along the entire length of a magnetic levitation element 240. The number of linear stators 230 shown in FIGS. 2A and 2B are examples, and a greater or lesser number of linear stators 230 may be used.

The linear stator 230 may be arranged to guide a corresponding magnetic levitation element 240 of the carrier 130 underneath. For example, a plurality of linear stators 230 may be disposed one after the other in a row, such as shown in FIG. 2A, extending in the X and/or Y-direction. In some embodiments, the one or more linear stators 230 are configured to remain stationary during contactless transportation of the carrier 130 along the magnetic levitation element 240 since the one or more linear stators 230 are coupled to a wall (e.g., top wall or side wall) of the process station 205.

The one or more linear stators 230 may include a plurality of stator poles 232, such as 2, 4, 6, 8 or more stator poles 232, as illustrated in FIG. 2B. The number of stator poles 232 shown in FIGS. 2A and 2B are examples, and a greater or lesser number of stator poles 232 may be used. The stator poles 232 may be protrusions, or teeth, that may project towards the carrier 130 and/or towards a magnetic levitation element 240 attached to the carrier 130. The plurality of stator poles 232 may define at least one comb structure. In some embodiments, a linear stator 230 may include two comb structures, each having a plurality of stator poles 232.

The magnetic levitation assembly 120, which includes the one or more linear stators 230, and the stator poles 232, may include, or be made of, a magnetic material, more specifically a ferromagnetic material. The magnetic material may be a non-permanent, or soft, magnetic material. The magnetic material may be a metal, such as electrical steel, silicon steel, ferritic steel, martensitic steel, or any other soft magnetic material.

The magnetic levitation element(s) 240 of the carrier 130 may include, or be made of, a magnetic material, such as a ferromagnetic material. The magnetic material may be a non-permanent, or soft, magnetic material. The magnetic material may be a metal, such as electrical steel, silicon steel, ferritic steel, martensitic steel, or any other soft magnetic material.

In some embodiments, as shown in FIG. 2A, the carrier 130 may be levitated and contactlessly transported in the X or Y-direction through the substrate processing system 100, for example when the carrier 130 is a substrate carrier for a large area substrate or a mask carrier carrying a mask for a large area substrate. The magnetic levitation element 240 is coupled to a portion of the top of the carrier 130, as illustrated. The magnetic levitation assembly 120, or at least a portion thereof, may be disposed above the carrier 130.

The carrier 130 is configured to be levitated and transported along the length of the magnetic levitation assembly 120 by use of the one or more linear stators 230 of the magnetic levitation assembly 120 that remain stationary within the process station 205. During contactless levitation and/or transportation of the carrier 130, the magnetic levitation element 240 faces at least one linear stator 230. The magnetic levitation element 240 may respectively face different linear stators 230 as the carrier 130 is transported along the magnetic levitation element 240.

As shown in FIG. 2B-2C, and in FIG. 3, the magnetic levitation element 240 may include an array of features 250. Any number of features 250 may be formed within an array of features 251. The features 250 may be protrusions, or teeth, that may project towards at least one linear stator 230 of the opposing magnetic levitation actuator assembly 120A. The raised segments of features 250, which include a magnetic material, may define a comb-like structure as illustrated in FIG. 2B and FIG. 3. Each magnetic levitation element 240 may also include a featureless element 260 adjacent to each array of features 250. The featureless element 260 may span the same or part of the length of the array of features 251. The upper surface 261 (see FIG. 2C) of the featureless element 260 may be planar (e.g., a flat surface), which the sensors 270 uses to measure and/or or detect a position of the carrier 130 during contactless levitation and/or transportation. In some embodiments, the featureless element 260 is formed from a ferrous material, such as being a strip of a ferromagnetic material embedded in or attached to the carrier 130. For example, the featureless element 260 may be made of magnetic stainless steel.

A pitch, or spacing, may be provided between adjacent stator poles 232 of a linear stator 230. The term “adjacent stator poles” (and likewise “adjacent features 250”) refers to poles of a same linear stator 230 that are adjacent to each other with respect to the direction defined by the magnetic levitation element 240, such as the transportation direction (e.g., X-direction in FIG. 2A). The pitch may be a distance, e.g. a horizontal distance, extending along the magnetic levitation element 240. Likewise, a pitch or spacing may be provided between adjacent features 250 of the magnetic levitation element 240. According to some embodiments, a first pitch between adjacent stator poles 232 of a linear stator 230 may be different from a second pitch between adjacent features 250 of the magnetic levitation element 240. Particularly, a ratio of the first pitch and the second pitch may be non-integer (the first pitch is not an integer multiple of the second pitch and the second pitch is not an integer multiple of the first pitch). The stator poles 232 of the linear stator 230 and the features 250 of the magnetic levitation element 240 may be provided according to a p/q configuration. A p/q configuration means that the distance (in the transportation direction) spanned by p consecutive adjacent stator poles 232 of the linear stator 230 includes a total of q features 250 of the magnetic levitation element 240. In some embodiments, q may be equal to p+1 or to p−1. For example, it may be the case that p=3 and q=2; or p=3 and q=4. In further examples, it may be the case that p=4 and q=3.

According to some embodiments, the one or more linear stators 230 of the magnetic levitation assembly 120 include a set of electromagnets. In light thereof, the one or more linear stators 230 are active magnetic systems that can provide an adjustable, controllable magnetic field. For example, each stator pole 232 of the linear stator 230 may include an electromagnet. The electromagnet may include a respective coil wound around each stator pole 232. Different winding schemes for winding the coils around each stator pole 232 may be provided. For example, the coils may be wound vertically, in that the coils are wound from top to bottom (clockwise) or from bottom to top (counter-clockwise). In some embodiments, the magnetic levitation element 240 may not include an electromagnet. The magnetic levitation element 240 may be a magnetically passive system, wherein the magnetic levitation element 240 is formed from a ferromagnetic material (e.g., permanent magnet, soft ferromagnetic iron), without any electromagnets mounted thereon. In some embodiments, the magnetic levitation element 240, or at least the features 250 formed thereon, include a ferromagnetic material such as a material selected from a group comprising transition metals (e.g., iron, nickel, cobalt) and their alloys, and alloys of rare-earth metals. In one example, the magnetic levitation element 240 includes a ferritic stainless steel, such as a 409, 430 and 439 stainless steel. The magnetic levitation element 240 may also include an electrical steel, silicon steel, martensitic steel, or any other soft magnetic material.

In some embodiments, the magnetic levitation assembly 120 includes two parallel magnetic levitation actuator assemblies 120A running in the X-direction configured to levitate carrier 130 and convey the carrier 130 in either the positive or negative X-direction. The carrier 130 similarly includes two parallel magnetic levitation elements 240 running in the X-direction. Each magnetic levitation element 240 is positioned on the carrier 130 to be underneath the one or more linear stators 230 of a respective magnetic levitation actuator assembly 120A running in the X-direction when the carrier 130 is being conveyed in the X-direction. Additionally, the magnetic levitation assembly 120 may also include two parallel magnetic levitation actuator assemblies 120A running in the Y-direction configured to levitate the carrier 130 and convey the carrier 130 in either the positive or negative Y-direction. The carrier 130 similarly includes two parallel magnetic levitation elements 240 running in the Y-direction. Each magnetic levitation element 240 is positioned on the carrier 130 to be underneath the one or more linear stators 230 of a respective magnetic levitation actuator assembly 120A running in the Y-direction when the carrier 130 is being conveyed in the Y-direction. As the carrier 130 moves in the Y-direction, the magnetic levitation elements 240 running in X-direction move out of alignment with the corresponding magnetic levitation actuator assemblies 120A running in the X-direction. The magnetic levitation actuator assemblies 120A running in the Y-direction are able to maintain levitation as the carrier 130 is moved in the Y-direction. The carrier 130 may be conveyed in the Y-direction to another station (e.g., from the fourth station 114 to the fifth station 115) until the magnetic levitation elements 240 running in the X-direction become aligned with corresponding magnetic levitation actuator assemblies 120A running in the X-direction where the carrier 130 may then be conveyed again in the X-direction.

The process station 205 may include the controller 150. In some embodiments, each process station 205 has its own controller 150 that is connected to a central controller of the substrate processing system 100. The controller 150 may be connected to the set of electromagnets of the linear stators 230 for controlling a current in the electromagnets, and thus the strength of the magnetic field generated by linear stators 230. The current can be increased to increase the attraction force of the set of electromagnets to raise the carrier 130 or decreased to lessen the attraction force of the set of the electromagnets to lower the carrier 130.

The controller 150 as described herein may be a single centralized controller or may be a distributed controller including a plurality of individual control units. The controller 150 may include a central processing unit (CPU), a memory and, for example, support circuits. To facilitate control of the carrier 130, the CPU may be one of any form of general-purpose computer processor that can be used in an industrial setting for controlling various components and sub-processors. The memory may be coupled to the CPU. The memory, or a computer readable medium, may be one or more readily available memory devices such as random-access memory, read only memory, a floppy disk, a hard disk, or any other form of digital storage either local or remote. The support circuits may be coupled to the CPU for supporting the processor in a conventional manner. The circuits in question include cache, power supplies, clock circuits, input/output circuitry and related subsystems, and the like. Software instructions and data can be coded and stored within the memory (e.g., non-transitory computer readable medium) for instructing the CPU. A program (or computer instructions) readable by the processing unit within the system controller determines which tasks are performable in the processing system. For example, the non-transitory computer readable medium includes a program which when executed by the processing unit are configured to perform one or more of the methods described herein. Preferably, the program includes code to perform tasks relating to monitoring, execution and control of the movement, support, and/or positioning of a substrate along with the various process recipe tasks and various processing module process recipe steps being performed within the system.

The one or more linear stators 230 including the electromagnets may, together with the magnetic levitation element 240, form a linear reluctance motor for providing both a contactless levitation and a contactless drive of the carrier 130. A linear reluctance motor is configured for providing a linear motion, or translational motion, of the carrier 130. A linear motor is distinguished from a rotary motor, which provides a rotational motion. The linear reluctance motor of the apparatus according to embodiments described herein provides a linear motion of the carrier 130 along the magnetic levitation assembly 120.

The process station 205 may include one or more sensors 270 for measuring or detecting a position of the carrier 130 during contactless levitation and/or transportation. In some embodiments, a plurality of sensors 270 are arranged in a linear array (e.g., row) adjacent to the linear array of linear stators 230, such as shown in FIG. 2B. For example, sensors 270 may be provided on opposite ends of each linear stator 230. Each sensor 270 is configured to detect the presence of a portion of the carrier 130. Each sensor 270 is also configured to detect a position of the carrier 130, which may include a vertical position and/or a horizontal position of the carrier 130, for example a horizontal position with respect to the transportation direction. The sensor 270 is a magnetic field detection sensor to detect the position of the carrier 130 through the membrane 206. Each sensor 270 may be connected to the controller 150. The sensor 270 may be high-precision sensor, which have a sensor resolution of 100 μm or less, particularly 10 μm or less, that is used to detect the relative position of a portion of the featureless element 260 of the carrier 130 to the sensor 270. Accordingly, the carrier 130 may be positioned vertically and/or horizontally in a target position with high precision. In some embodiments, the sensors 270 are included in the magnetic levitation assemblies 120.

The process station 205 according to embodiments described herein may include one or more sensors 270 for detecting a position of the carrier 130 with respect to a transportation direction of the carrier 130. The controller 150 may be configured to control the reluctance-based drive force in response to a signal provided by the one or more sensors 270 to position the carrier 130 in a target position with respect to the transportation direction. The reluctance-based drive force may be configured to align the carrier 130 along the magnetic levitation element 240 or transport direction. By controlling amplitude and phase angle of an AC signal provided to the coils coupled to the stator poles 232, the dynamic motion characteristics of the magnetic levitation elements 240 and thus the carrier 130, such as the amount of jerk, acceleration, velocity, and finally horizontal position can be adjusted and achieved. The controller 150 may cause the magnetic levitation assembly 120 to adjust the roll, pitch, and/or yaw of the carrier 130 if the sensors 270 detect that the carrier 130 is not level, such as having an unacceptable roll, pitch, and/or yaw. The controller 150 may also cause the magnetic levitation assembly 120 to maintain the carrier 130 in a level orientation as it passes through the second region 208. In some embodiments, three or more sensors 270 located above different portions of the carrier 130 may be used to detect orientation of the carrier 130, such as the roll, pitch, and/or yaw of the carrier 130. The controller 150 may instruct the magnetic levitation assembly 120 to adjust the position of the carrier in the X and/or Y direction if the sensors 270 detect the carrier 130 is out of a desired alignment in the X and/or Y directions. The controller 150 may instruct the magnetic levitation assembly 120 to change the position of the carrier in the Z-direction based on the sensors 270, such as raising and lowering to carrier relative to the membrane 206 to adjust or maintain a gap between the carrier 130 and the membrane 206. For example, the controller 150 may reduce the electrical current to the set of electromagnets of the linear stators 230 to lower the carrier 130 in the Z-direction and may increase the current to the set of electromagnets of the linear stators 230 to raise the carrier 130 in the Z-direction. In some embodiments, the carrier 130 is maintained at a desired position in the Z-direction, such as maintaining the carrier 130 in a level orientation, by adjusting the current to the linear stators 230 in responses to changes in position of the carrier 130 detected by the sensors 270. Thus, the controller 150 may respond to the position of the carrier 130 detected by each sensor 270 to adjust a position of the carrier 130 in the X, Y, and/or Z directions at different positions of the carrier 130 and/or to control the orientation of the carrier 130.

FIG. 2C illustrates a schematic partial cross-sectional view of the portion 200 to illustrate the magnetic levitation actuator assembly 120a and carrier 130. The sensors 270 and stators 230 are shown adjacent one another in the Y-direction. The sensor 270 and stator 230 are each attached to a frame member 220 of the magnetic levitation actuator assembly 120a. The frame member 220 may extend along the x-direction above the membrane 206. A plurality of stators 230 may be attached to the frame member 220 arranged in a linear array (e.g., row) that is parallel to a linear array of sensors 270 attached to the frame member 220. The frame member 220 may be attached to a wall of the process station 205 in the first region 207 to maintain a fixed distance between the top side of the membrane 206 and the sensor 270 and the stator 230. In some embodiments, sensor 270 is positioned over the membrane 206 or in a recess formed in the membrane 206 such that the sensor 270 is not in contact with the membrane. In other words, a clearance 271 may be present between the membrane 206 and the sensor 270.

The stator 230 is shown in FIG. 2C directly above the one or more features 250 of the magnetic levitation element 240 that are located on the other side of the membrane 206. The sensor 270 is positioned adjacent to the stator 230 and is directly above the featureless element 260. A gap G1 is present between the featureless element 260 and the membrane 206. The featureless element 260 provides a uniform surface for the sensor 270 to detect. The sensor 270, which positioned a fixed distance from the membrane 206, is able to detect changes in the size of the gap G1 (e.g., distance between the membrane 206 and the featureless element 260) through the membrane 206 such that the controller 150 is able to determine the position of the carrier 130 underneath the sensor 270 in the Z-direction. In some embodiments, the sensor 270 may have one or more electromagnets and one or more magnetic field sensor elements that are able to detect changes in magnetic flux density of a magnetic field generated by the one or more magnets in the sensor 270 as the size of the gap G1 changes. The magnetic field sensor element may be a Hall Effect element, a giant magnetoresistance (GMR) element, or a tunnel magnetoresistance (TMR) element, or other suitable magnetic field sensor element. It has been found that GMR and/or TMR sensors produce a signal with less noise and are more sensitive than a Hall Effect sensor element providing higher Signal-to-Noise-Ratio (SNR).

The size of the gap G1 modulates the magnetic field of the one or more magnets of the sensor 270 so that the magnetic flux density detected by the one or more magnetic field sensor element varies based on the size of the gap G1. The configuration of the magnets and relative position of the magnetic field sensor elements to the magnets affects whether increasing the size of the gap G1 increases or decreases the magnetic flux density measured by the magnetic field sensor elements. The sensor 270 may convert the magnetic flux density detected by the sensor elements into a voltage signal that can be used by the controller 150 or processor on the sensor 270 to determine the size of the gap G1. The dimension of the gap G1 may be determined by correlating the voltage signal generated by the sensor 270 to the size of the gap G1. For example, controller 150 may have a lookup table stored in the memory that indexes the voltage of the voltage signal to a corresponding size of the gap G1.

The one or more magnetic field sensor elements of sensor 270 may measure one or more components of a magnetic flux density vector, such as the x-component of the magnetic flux density vector, to determine the size of the gap G1. For example, the magnetic field sensor elements may measure the x-component of the magnetic flux density vector to determine the size of the gap G1.

Referring back to FIG. 2C, the underside 211 of the membrane 206 is used as a datum to determine the size of the gap G1. In some embodiments, the membrane 206, however, may deform (e.g., bow, deflect) due to the pressure differential between the first region 207 and second region 208. The amount that the membrane 206 deforms varies due to differences in the thickness of the membrane 206. In some embodiments, the membrane 206 may be composed of a material that is attracted to the magnetic fields generated by the stators 230 and the magnet(s) in the sensors 270. This attraction force generated by the stators 230 and magnet(s) of the sensors 270 may cause the membrane 206 to deform. Additionally, the membrane 206 may deform due to thermal expansion and contraction. Thus, the underside 211 of the membrane 206 may not be a uniform flat surface but instead may vary along the length of the membrane 206.

In some embodiments, the controller 150 compensates for the variations in the position of the underside 211. To compensate for the variations in the position of the underside 211 of the membrane 206, the carrier 130 is occasionally, some times periodically, raised into engagement with the membrane 206 as the carrier 130 is transported through the second region 208. The controller 150 may use the information obtained by one or more sensors 270 while the carrier 130 is engaged with the membrane 206 to determine the position of the underside 211 of the membrane 206 to calibrate the one or more sensors 270.

For example, the carrier 130 may be lifted to engage the top surface 212 of the features 250 with the membrane 206. The top surface 212 of the features 250 have a fixed position relative to the carrier 130, such as having a fixed position relative to the featureless element 260. The sensors 270 then determines the size of the gap G1 present while the carrier 130 is engaged with the membrane. Each sensor 270 may sense a different size of the gap G1 based on the variation of the deformation of the membrane 206 underneath the specific sensor 270. In some embodiments, the detected gap G1 may then be compared to a reference gap size R1. The reference gap size R1 is the size of the gap G1 that would be present if the underside 211 of the membrane 206 was undeformed. FIG. 2C shows the reference gap size R1 as the differential between the top surface 212 of the feature 250 and the upper surface 261 of the featureless element 260. The controller 150 uses the differential in the detected gap size and the reference gap size R1 to determine the actual position of the underside 211 of the membrane 206 underneath each sensor 270. The controller 150 then calibrates the output of a sensor 270 based on the actual position of the underside 211 of the membrane 206 beneath the sensor 270 to determine the size of the gap G1. In other words, the controller 150 uses the determined position of underside 211 of the membrane 206 as the datum for the sensor 270. The sensor assembly 270 may be calibrated by adjusting the voltage output of each sensor 270 by a factor to account for the position of the underside 211 of the membrane 206.

The controller 150 may repeatedly engage the carrier 130 with the membrane 206 to calibrate the sensor 270. For example, the controller 150 may cause the stators 230 to lift the carrier 130 into engagement with the membrane 206 after the carrier 130 travels a distance in the transportation direction to allow the controller 150 to calibrate the sensors 270 above the carrier 130. This distance may be equivalent to the length of one stator 230.

In some embodiments, the sensors 270 are calibrated by engaging the carrier 130 with the underside 211 of the membrane 206 to determine the position of each sensor 270 relative to the membrane 206, such as the position relative to the underside 211. Each sensor 270 in the linear array of sensors 270 may vary in position relative to the membrane 206. Additionally, the magnetic field sensor elements in each sensor 270 may vary in position relative to the membrane 206. Engaging the carrier 130 with the membrane 206 allows the controller 150 to determine the variations in position of each sensor 270 and the magnetic field sensor elements. The voltage output of each sensor 270, such as the output of each magnetic field sensor element, may be adjusted based on a factor to account for the variation in position with respect to the membrane 206.

Each stator 230 in the array is preferably located at the same vertical position relative to the membrane 230 to facilitate levitating and moving the carrier 130. In some embodiments, the vertical position of the stators 230 relative to the membrane 206 vary. For example, the variation may be due to slight difference in the size of the stators 230 during manufacturing. As another example, positional differences between stators 230 may be the result of the attachment of the stators to the frame member 220. The controller 150 may supply a current to each stator 230 to account for the variation in the vertical position of the stators 230 to maintain the carrier 130 in a level orientation. For example, the controller 150 may supply an increased current to a stator 230 that is farther away from the membrane 206 to generate a similar attraction force to stators 230 positioned closer to the membrane 206.

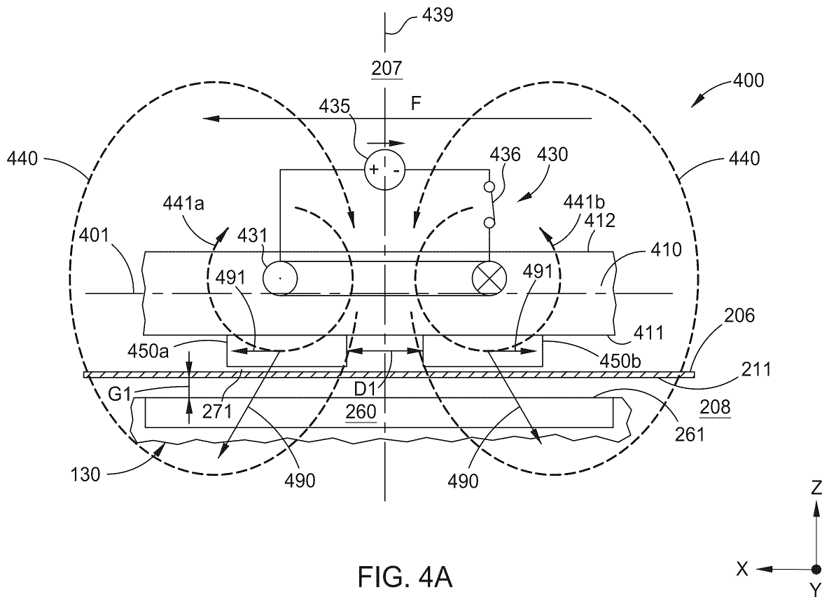

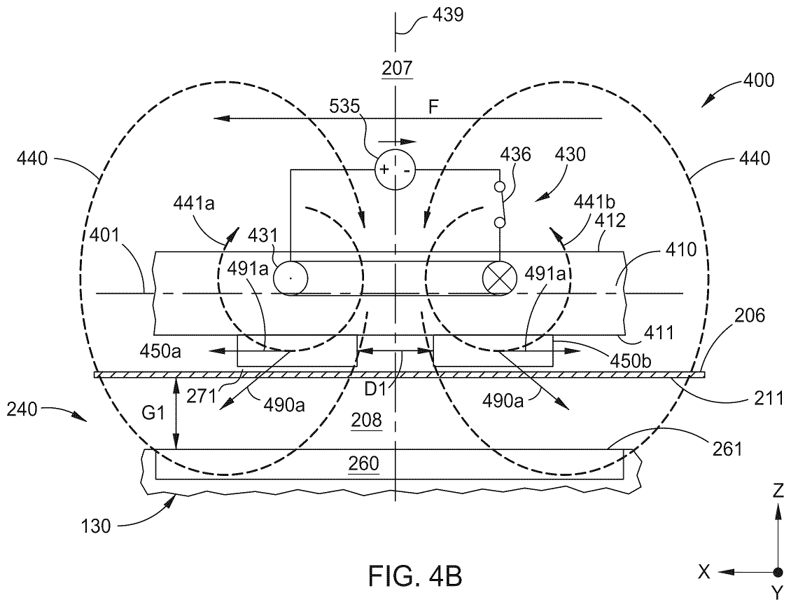

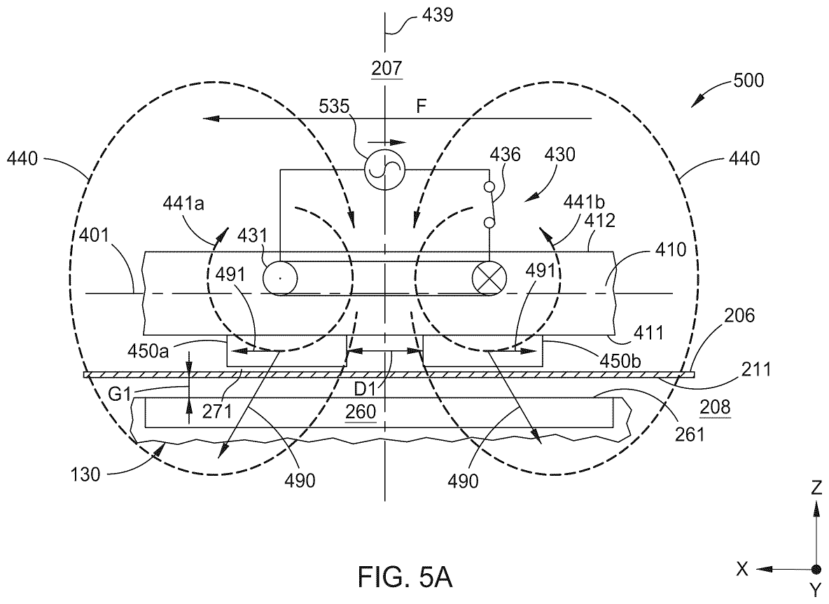

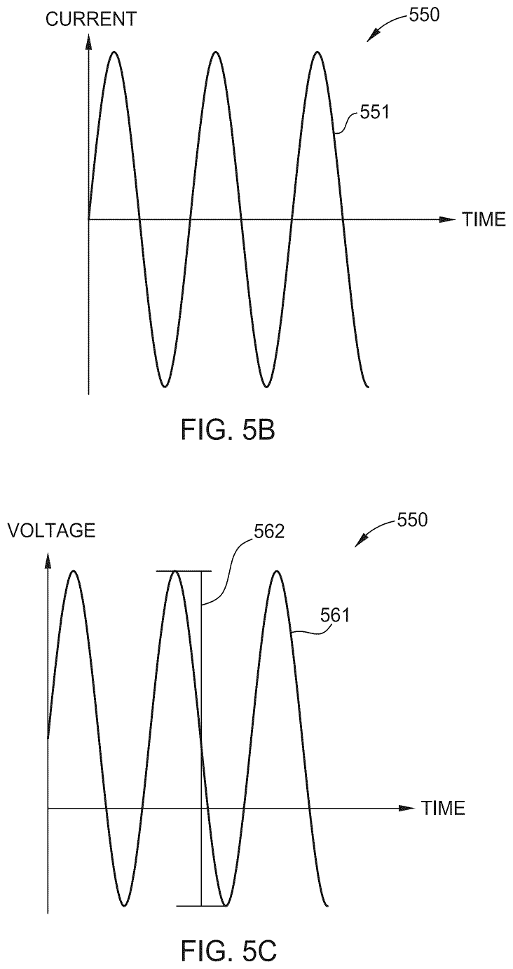

The sensor 270 includes one or more electromagnets 430 (FIGS. 4A-5A) to generate the magnetic field that is modulated by the changing size of the gap G1 and monitored by the one or more magnetic field sensor elements (e.g., sensor elements 450a, 450b illustrated in FIGS. 4A-5A). The electromagnets include at least one coil. A current, such as a direct current (DC) or an alternating current (AC), is supplied to the at least one coil to generate the magnetic field. The current may be supplied from a constant current source such that the electromagnet generates a field with a consistent field strength at a desired field strength set point, such as repeatedly generating a magnetic field with the same or substantially the same strength to detect different carriers 130 that are circulated through the process station 205. Alternatively, the sensor 270 can be operated according to the so called compensation principle in a constant field strength mode. Therefore, the sensor elements 450 detect the magnetic field strength and the current is actively controlled in a manner, that the field strength is constant for different gaps G1. The electrical current to the coil will therefore change in amplitude and this amplitude is used as measurement for G1.

In some embodiments, the current to the electromagnet of the sensor 270 is increased or decreased in response to the detected magnetic field in an effort to maintain a consistent magnetic field strength detected by the magnetic field detection elements of the sensor 270. The current to each sensor 270 may be increased or decreased independently of the other sensors 270.

In some embodiments, the current output by the current source to the at least one coil can be based on output signal of the magnetic field detection elements, such as the amount of current being adjusted based on the flux density detected by the magnetic field detection elements. The current can be adjusted to maintain a relatively constant magnetic flux generated by the at least one coil. In other words, the current source can be a controllable current source that adjusts the current supplied to the at least one coil based on input (e.g., feedback) from magnetic field detection elements to achieve minimal deviation from the desired magnetic flux.

During the system operation, the substrate 140 is processed within a processing region 204 of the process station 205. The heat generated during the process within the processing region 204, along with the heat generated by the components within the magnetic levitation actuator assembly 120A, affect the temperature that the sensors 270 experience within the first region 207. Thus, the temperature that the sensor 270 experiences within the first region 207 may vary over time. Permanent magnets are susceptible to changes in temperature. An increase in the temperature reduces the strength of a permanent magnet's magnetic field. An unknown and variable magnetic field adversely impacts the ability of the sensor to accurately detect the size of the gap. Additionally, permanent magnets suffer irreversible loses in magnetic field strength when exposed to temperatures that exceeds the maximum operating temperature of the permanent magnet. Exposing a permanent magnet to temperatures above the Curie temperature results in a permanent loss of magnetism. Thus, using a permanent magnet as a magnetic field source may not be practical in certain environments, such where the permanent magnet experiences temperature variations and temperatures that cause permanent losses in the magnetic field strength.

An electromagnet can be controlled to generate a consistent magnetic field as the temperature fluctuates within the first region 207. Additionally, electromagnets can be used in environments that cause irreversible or permanent magnetic field strength losses in a permanent magnet. Therefore, using an electromagnet as the magnetic field source of the sensor 270 avoids the temperature limitations of permanent magnets and allows for the rapid adjustment and control of the generated magnetic field.

The sensor 270 may include a DC or AC current source as noted above to supply a current to one or more coils 431 (FIGS. 4A-4B) to generate a magnetic field. It is believed that supplying a DC current to a coil creates a magnetic field that more readily penetrates the membrane 206 than a magnetic field created by supplying an AC current due to the generation of eddy currents in the membrane 206. Additionally, a DC current source is cheaper to implement than an AC current source. Furthermore, a magnetic field generated by a DC current source does not induce eddy current in the membrane 206 or featureless element 260.

If the frequency of the AC current is too high, then the resulting magnetic field generates eddy currents in the membrane and/or featureless element 260 depending on the conductivity and thickness of the membrane 206 and/or the featureless element 260. Eddy currents can obscure the signal generated by the magnetic field sensor elements and can cancel out the signal. The eddy current induced by the AC current is proportional to the conductivity of the material. Thus, for AC current applications, it is preferable to form the membrane 206 and featureless element 260 from a material having a high electric resistivity to keep the induced eddy currents low. In some embodiment, the featureless element 260 may be formed from ferrite or a ferritic steel. In some embodiments, the featureless element 260 may be formed from a magnetic stainless steel (e.g., type 409, 430 and 439) and the membrane 206 may be formed from a non-magnetic stainless steel (e.g., type 301, 304, T304, 316) or even ceramics.

In some embodiments using an AC current source, the sensor 270 outputs a changing (e.g., triangular, rectangular or sinusoidal) voltage signal. The peak-to-peak (e.g., positive peak to negative peak) of the sinusoidal voltage signal is detected by the sensor elements. This peak-to-peak value is correlated to the size of the gap G1, where a larger peak-to-peak value will signify a smaller gap G1, versus a smaller peak-to-peak value signifies a larger gap G1. If the frequency of the AC current is too low, then the sensor 270 will have a slow reaction time due to the amount of time it takes to determine the peak-to-peak value of the sinusoidal voltage signal. Thus, the frequency of the AC current is selected to manage and/or minimize the eddy currents while providing a satisfactory reaction time. For example, the frequency of the AC current supplied to the one or more coil of the sensor 270 may be between about 1 kHz and about 3 kHz, such as 1 kHz, such as about 1.5 kHz, such as 2 kHz, such as about 2.5 kHz, such as about 3 kHz. For example, the current is switched between a positive and a negative voltage value with a certain frequency and the resulting current shape results in triangular rectangular waveform depending on the frequency used and the inductivity of the coil. A value of the magnetic field can then be taken in a defined time after switching. This can be also correlated to the control of the coil current of the actuator unit 230 to minimize disturbance of switching actions form the actuator unit 230 initiated by controller 150. When the membrane 206 is not formed from stainless steel or conductive material, the frequency of the AC current supplied to the one or more coils of the sensor 270 may exceed 3 kHz, such as being 5 kHz, such as being 10 kHz, such as being 15 kHz, such as being 20 KHz.

The magnetic field generated by the electromagnet of the sensor 270 exerts an attraction force on the carrier 130. This attraction force generated by the sensors 270 can adversely affect the ability of the linear stators 230 to control the levitation and drive the carrier 130 without the carrier 130 being lifted into contact with the membrane 206. Thus, the amount of current through coil is selected to generate a magnetic field that facilitates detecting the measurement of the gap G1 without applying a significant attraction force on the carrier 130.

Additionally, the combined attraction force due to the presence of a plurality of sensors 270 can similarly adversely impact the ability of the liner stators 230 to contactlessly levitate and drive the carrier 130. Therefore, in some embodiments, the electromagnets can be turned-on when desired to measure the gap G1 and turned-off when measuring the gap G1 is not desired. In some embodiments, the sensor 270 may be powered down when not needed, such as by reducing the current to the electromagnet to decrease the strength of the magnetic field. Thus, the attraction force applied by a plurality of sensors 270 can be managed to allow the stators 230 to levitate and drive the carrier 130 without creating motion control related problems, such as causing the carrier 130 to contact the membrane 206 when it is stationary or moving through the system.

The sensor 270 is disposed over empty space beneath the membrane 206 when the carrier 130 is not beneath the sensor 270. The sensor 270 may be used to determine if the carrier 130 is disposed underneath the sensor 270, such as using the sensor 270 to track the position of the carrier 130 through the second region 208 of the process station 205. The size of the space beneath the sensor 270 is greatly reduced when the carrier 130 moves underneath the sensor 270 to fill the space and create the gap G1 between the carrier 130 and the membrane 206. Thus, the sensor 270 may detect that the carrier 130 has moved beneath the sensor 270 if the magnetic flux density meets a threshold value, such as a threshold value based on the rate of change in the magnetic flux density that indicates that the carrier 130 has moved underneath the sensor 270. Additionally, the controller 150 may reduce or stop current flowing to a coil within a linear stator 230 if a sensor 270 detects that the carrier 130 is no longer beneath the linear stator 230, such as after the carrier 130 passes underneath the stator 230 as it travels into a different process station. The ability to monitor and control the magnetic fields generated by the stators 230, and in some cases, as discussed further below, the magnetic fields generated by the sensors can be useful to avoid the generated magnetic fields from affecting the processes performed in a process station (e.g., stations 112-113 and 116-117).

For example, the sensor 270 may receive a voltage signal that indicates that the carrier 130 is not located underneath the sensor 270, such as outputting a voltage signal that is outside of a threshold value. The threshold value may be the maximum size of a gap stored in a lookup table in the controller 150. This maximum size of the gap G1 may be the largest dimension of the gap G1 present when the carrier 130 is disposed under the sensor 270. For example, the maximum size of the gap G1 may be the size of the gap G1 present when the carrier 130 is resting on a bottom surface of the process station 205 or engaged with one or more landing rails disposed underneath the carrier 130 within the second region 208. Once the carrier 130 is located underneath, the sensor 270 outputs a voltage signal that is within the range of input voltages of the stored lookup table, indicating that the carrier 130 is underneath the sensor 270.

In some embodiments, the sensor 270 is positioned over a portion of the carrier 130 that has features, such as being positioned over the array of features 250. The position of the carrier 130 in a translation direction, in some embodiments, can be detected by the detection of the passage of or presence of an edge of the features 250 near or relative to the sensor 270. The controller 150 is configured to account for the differential heights of the features 250.

The controller 150 may control the position of the carrier 130 in the Z-direction based on the size of the gap G1 detected by the sensors 270. In some embodiments, the controller 150 may adjust the current to the linear stators to maintain the size of the gap G1. For example, the gap G1 may be maintained at a distance less than 10 mm, such as 9 mm, such as 8 mm, such as 7 mm, such as 6 mm, such as 5 mm, such as 4 mm, such as 3 mm, such as 2 mm, such as 1 mm. In some embodiments, the process station 205 is arranged such that the gap G1 is in either the X-direction or Y-direction rather than the Z-direction. The sensor 270 may be used to control the size of the gap G1 in the X-direction and/or Y-direction.

The controller 150 may maintain the size of the gap G1 by closed loop control. For example, the controller 150 may have a desired distance of the gap G1 as a stored value, such as a gap distance of 5 mm. The controller 150 may use the sensors 270 to determine the size of the gap G1 present between the membrane 206 and the featureless element 260. If the detected size is equal to the stored value, then the controller 150 does not cause the stators 230 to adjust the z-position of the carrier 130. In some embodiments, the controller 150 may increase the current to one or more stators 230 if the gap G1 is greater than the stored value to lift the carrier 130 to adjust the gap G1 to the stored value. Similarly, the controller 150 may decrease the current to one or more stators 230 if the gap G1 is less than the stored value to lower the carrier 130 to adjust the gap G1 to the stored value.

In some embodiments, the controller 150 may also not cause the linear stators 230 to adjust the z-position of the carrier 130 if the detected size is within a threshold range of the stored value. For example, the threshold range may be 1 mm, such as 0.9 mm, such as 0.8 mm, such as 0.7 mm, such as 0.6 mm, such as 0.5 mm, such as 0.4 mm, such as 0.3 mm, such as 0.2 mm, such as 0.1 mm, such as 0 mm. In other words, the controller 150 may not adjust the z-position of the carrier 130 if the detected position is within the threshold range, such as being within plus or minus 0.5 mm of 5 mm as an example. If the controller 150 determines that the detected position is outside of the threshold range, then the controller 150 causes the stators 230 to adjust the z-position of the carrier 130 to return the size of the gap G1 to the stored value. Additionally, the gap size detected by each sensor 270 may differ if the carrier 130 is not level. The controller 150 may use the distance detected by each sensor 270 to adjust the pitch or tilt of the carrier 130 to return the carrier 130 to a level orientation. This process may repeat cyclically during the operation of the process station 205 to maintain the desired size of the gap G1, and thus z-position of the carrier 130.

The process station 200 includes a substrate support 209 disposed below the processing chamber 201. The processing chamber 201 includes a process kit assembly 202, and a source assembly 203. As shown, the substrate support 209 is disposed below the process kit assembly 202 and source assembly 203. The carrier 130 is shown in a park position, as indicated by the reference sign 208A, within the second region 208. The carrier 130 is moveable to a transfer position 208B (shown in dashed lines and indicated by reference sign 208B) above the substrate support 209.

The substrate support 209 is moveable in the Z-direction within the second region 208 to one or more positions. While the carrier 130 is moving within the process station 200, the substrate support 209 may be positioned in a lower position to allow the carrier 130 to move to through and/or to one or more positions within the second region 208 without contacting the substrate support 209.

The carrier 130 is moved to the transfer position 208B above the substrate support 209 to facilitate the transfer of the object 140 on the carrier 130 to lift pins of the substrate support 209. The carrier 130 is then moved to the park position 208A (e.g., position opposite to the transfer position) after the object 140 is transferred to the lift pins. The carrier 130 is clear from the substrate support 209 when in the park position 208A to allow the substrate support to move vertically from the lower position to a process position with the transferred object 140 disposed thereon.

The substrate support 209 is engaged with the process kit assembly 202 when in the process position. In some embodiments, the process kit assembly 202 includes one or more components to seal against the substrate support 209 when the substrate support 209 is in the process position. For example, the substrate support 209 and process kit assembly 202 may at least partially defined the process region 204 within the process station 205 where the substrate 140 is subjected to a process performed by the source assembly 203. The process region 204, which is defined by surfaces of the substrate 140, the substrate support 209, the process kit assembly 202 and the source assembly 203, is isolated from the second region 208 when the substrate support 209 is in the process position. For example, the source assembly 203 may be configured to deposit a layer via a physical vapor deposition (PVD) process onto the substrate 140. Once the process performed by the source assembly 203 is complete, the substrate support 209 is lowered from the process position to a lower position to allow the carrier 130 to return to the transfer position 208B where the substrate 140 is transferred from the lift pins back onto the carrier 130.

The source assembly 202 may be adapted to perform a physical vapor deposition (“PVD”), chemical vapor deposition (“CVD”), plasma enhanced chemical vapor deposition (“PECVD”), atomic layer deposition (“ALD”), plasma enhanced atomic layer deposition (“PEALD”), etch, lithography, ion implantation, ashing, cleaning, thermal process (e.g., rapid thermal processing, anneal, cool down, thermal management control) degas, and/or other useful substrate processes.

In some embodiments, the membrane 206 may have an opening allowing the substrate support 209 to be raised upward toward the process chamber 201 into engagement with the processing kit assembly 202. In some embodiments, the process station 205 includes one or more separate membranes 206 for each magnetic levitation actuator assembly 120A. The process chamber 201 may disposed between separate membranes 206.

In some embodiments, the controller 150 may turn-off some or all of the sensors 270 while the substrate 140 is being processed in the processing region 204. The controller 150 may also power down some or all of the sensors 270, without fully turning-off the sensors 270, to reduce the strength of the magnetic field generated by the sensors 270. The sensors 270 are powered down by decreasing the current supplied to the electromagnet from an operating current to reduce the strength of the magnetic field. The current is then increased back to the operating current when desirable to use the sensor 270 to obtain a measurement. In some embodiments, some sensors 270 are fully turned-off (e.g., the current is stopped) while others are powered down. The stators 230 may also be fully or partially turned-off (e.g., powered down) when the substrate 140 is being processed. For example, the stators 230 may be used to move the carrier 130 to the park position prior to processing the substrate 140 within the processing region 204. Once the carrier 130 is in the park position 208A, the controller 150 operates the stators 230 to land the carrier 130 on the bottom of the processing chamber 205 or on a landing rail assembly disposed in the second region 208. Once the carrier 130 is landed, the stators 230 are powered down (e.g., current is reduced) to reduce the strength of the magnetic field or fully turned-off to stop the generation of magnetic fields. The process within the processing region 204 may then begin. Turning-off and/or powering down the stators 230 and the sensors 270 during processing mitigates the impact of the magnetic fields generated by either the stators 230 or the sensors 270 on the process within the processing region 204.

FIG. 3 illustrates an example carrier 300 that includes a base 310 and the magnetic levitation elements 240 of FIGS. 2A-2C, in accordance with embodiments of the present disclosure. In some embodiments, the carrier 130 described above may be implemented as the carrier 300. The carrier 300 of FIG. 3 may be similar to the carrier 130 of FIGS. 2A-2C, and everything discussed herein with respect to the carrier 130 may also apply to the carrier 300.

In some embodiments, the magnetic levitation element 240 of the carrier 300 may be coupled to the base 310. The carrier 300 may also include an opening 330 in the base 310. The carrier 300 may further include one or more substrate support members 342 coupled to the base 310 to support the object 140. Although the object 140 is illustrated in FIGS. 3 as a substrate, the carrier 300 may also be configured to carry other objects. For example, the carrier may be configured to carry a mask, shutter, process kits parts, or other objects used in semiconductor processing, as described above. The carrier 300 may also be configured to transport shutter or process kits parts.

In some embodiments, the magnetic levitation element 240 may include or be implemented as one or more rails (e.g., rails 242, 244, 246, 248). The rails 242, 244, 246, 248 may each be aligned in a certain direction relative to the base 310. In some cases, the magnetic levitation element 240 of the carrier 300 may include a first rail 242 aligned in a first direction (e.g., the X-direction). The magnetic levitation element 240 may also include a second rail 244 aligned in a second direction (e.g., the Y-direction). The magnetic levitation element 240 may also include a third rail 246 aligned in the Y-direction and is aligned parallel to the second rail 244. The magnetic levitation element 240 may also include a fourth rail 248 aligned in the X-direction, and is aligned parallel to the first rail 242. Although the carrier 300 in FIG. 3 is illustrated as having four rails 242, 244, 246, 248, however, any number of rails may be used in the carrier 300.

The dimensions of the carrier 300 (including the base 310 and the rails 242, 244, 246, 248) may be based on at least one of the size of the stations 111-118, the location of the sensors 270 in the stations 111-118, or the size of the objects (e.g., the object 140) being transported by the carrier 300. The dimensions of the carrier 300 may also be selected to facilitate the stability of the carrier 300 during transportation of the object(s) 140, as well as ensure the stability of the carrier 300 when nothing is transported. The carrier 300 may be also be configured to be large enough to support the object 140 (or multiple objects 140, as described below) and small enough to pass into, through, and out of stations (e.g., stations 111-118) of a substrate processing system (e.g., substrate processing system 100), as described above.

The features 250 may be arranged on the rails 242, 244, 246, 248. In some embodiments, a pitch and/or spacing may be provided between adjacent features 250, as described above. The features 250 may also be arrange side by side. As illustrated in FIG. 3, the array of features 250 of the first rail 242 may be aligned in the X-direction along a surface of the first rail 242, the array of features 250 of the second rail 244 may be aligned in the Y-direction along a surface of the second rail 244, the array of features 250 of the third rail 246 may be aligned in the Y-direction along a surface of the third rail 246, and the array of features 250 of the fourth rail 248 may be aligned in the X-direction along a surface of the fourth rail 248. In some embodiments, the features 250 may be arranged linearly. A gap between each feature may vary between features 250, or may be the same along the rails 242, 244, 246, 248.

In some embodiments, the features 250 of the rails 242, 244, 246, 248 may cover a portion of the top of the carrier 130. The featureless element 260 of the magnetic levitation elements 240 is shown adjacent to the features 250 of each rail 242, 244, 246, 248. The featureless element 260 may be included on the top of one or more of the rails 242, 244, 246, 248 of the carrier 300, and may be implemented as a featureless track that is aligned with the array of features 250. In some embodiments, the magnetic levitation elements 240 may each include an outer portion and an inner portion. In these embodiments, the features 250 may be located on one or more outer portions of the magnetic levitation elements 240 and the featureless element 260 may be located on one or more inner portions of the magnetic levitation elements 240, as illustrated in FIG. 3. In some embodiments, the featureless element 260 may be a featureless portion of a surface of the magnetic levitation element 240 rather than being an element embedded on or attached to the magnetic levitation element 240. In some embodiments, at least a portion of the base 310 may be featureless and may be planar (e.g., substantially flat) and configured to enable the sensors 270 to measure and/or or detect a position of the carrier 300 during contactless levitation and/or transportation. That is, at least a portion of the base 310 may function as the featureless element 260.

The base 310 of the carrier 300 may be formed from a non-magnetic material and vacuum compatible material, such as metal (e.g., aluminum (AI), non-magnetic stainless steel (e.g., 316 SST) or titanium (Ti)). In some embodiments, it is beneficial to select the material from which the carrier 300 is made to include a material that can also withstand high processing temperatures. In one example, the substrate carrier 300 is made from a ceramic material (e.g., alumina, quartz, zirconia, etc.). In some cases, the substrate carrier 300 may be coated with an electrically conductive coating to resolve any charge build-up issues in the substrate carrier 300 during processing within the process station 205. In some embodiments, the rails 242, 244, 246, 248 may include a magnetic material, and the base 310 may not include a magnetic material. By using a different material in the base 310 than the rails 242, 244, 246, 248, the carrier 300 may be configured to be lighter, and/or may be cheaper to manufacture. In some embodiments, the base 310 may be made from the same material as the rails 242, 244, 246, 248. For example, the base 310 and the rails 242, 244, 246, 248, including the featureless element 260, may be made of magnetic stainless steel.

FIGS. 4A and 4B are each a partial cross-section of the process station 205 that show a schematic side view of a magnetic sensor 400. The sensor 270, described herein, may include the sensor 400 to detect the gap G1 between a carrier, such as carrier 130 or 300, and the membrane 206. The magnetic sensor 400 includes a electromagnet 430, a first sensor element 450a, a second sensor element 450b, and a magnetic field permeable base 410, or for simplicity of discussion, often referred to herein as a base 410.

The base 410 has a first side 411 and a second side 412. The first and second sensor elements 450a, 450b are disposed on the first side 411. The electromagnet 430 incudes at least one coil 431 and a direct current (DC) source 435. The DC current source 435 may be a constant DC current source. In some embodiments, the coil 431 is a wound wire, or even a conductive trace formed in a printed circuit board (PCB), that includes a plurality of turns. The at least one coil 431 is disposed between the first and second sensor elements 450a, 450b. An electromagnetic field 440 is generated by the coil 431 when the DC constant current source 435 supplies the current to the coil 431. The DC constant current source 435 may selectively supply direct current to the coil 431 to generate the magnetic field 440. A switch 436 may be coupled to the coil 431 and to the DC constant current source 435, and the controller 150 may open (e.g., switch off) the switch 436 to stop the flow of current from DC current source 435 to the coil 431 to stop the generation of the magnetic field 440 and close (e.g., switch on) the switch 436 to complete the circuit to cause the generation of the magnetic field 440.

In some embodiments, the base 410 is a printed circuit board (PCB) with the first and second sensor elements 450a, 450b being connected to the one or more circuits formed on or within the PCB 410. The one or more coils 431 may formed (e.g., printed) in the PCB 410. For example, the one or more coils 431 may be disposed on one or more layers of the PCB 410. In some embodiments, the one or more coils 431 may be one or more layers of spiral coils disposed in the PCB. The PCB 410 may be in communication with the controller 150. For example, the PCB 410 communicates the measurements and/or data obtained by the first and second sensor elements 450a, 450b to the controller 150 by delivering a measurement signal (e.g., voltage signal) to the controller 150. For example, the controller 150 may receive a voltage reading from the magnetic sensor 400 that is converted into a size of the gap G1, wherein the magnitude of the voltage provided in the signal relates to the size of the gap G1. In some embodiments, the base 410, including embodiments where the base 410 is a PCB, may be formed to include one or more recesses or pockets to at least partially receive the first and second sensor elements 450a, 450b and the electromagnet 430. The PCB 410 may be oriented horizontally as shown in FIG. 4A. Using a PCB as the base 410 also decreases manufacturing costs since an automated process can be used to attach the sensor elements 450a, 450b, and the components of the electromagnet 430 instead of hand soldering of the components together. In some embodiments, the base 410 may include shaping features that may be attached to or integral with the base 410 to shape a magnetic field 440 emanating from the at least one coil 431. The shaping features my include structural elements, such as conductive portions of the base, conductive plates, sheet metal, ferromagnetic elements, or ferrite elements, etc., that are able to block and/or guide the shape of the magnetic field generated by the coil 431.

In some embodiments, the base 410, including embodiments where the base is a PCB, may be formed from, fully coated by, or partially coated by a vacuum compatible material. In some embodiments, the first side 411 is coated with a vacuum compatible material.

The at least one coil 431 is oriented such that the magnetic axis 439 of the electromagnet 430 is perpendicular or substantially perpendicular to a longitudinal axis 401 of the base 410 as shown in FIG. 4A, and also preferably the upper surface 261 of the featureless element 260 of a magnetic levitation element 240. In other words, the coil 431 is oriented such that the poles of the generated magnetic field 440 extend in the vertical direction (e.g., Z-direction). FIG. 4A shows the coil 431 oriented parallel to the longitudinal axis 401 of the base 410 and also parallel to the upper surface 261 of the featureless element 260 such that the magnetic axis 439 is perpendicular or substantially perpendicular to a longitudinal axis 401 of the base 410.

The coil 431 may be a planar coil as shown in FIG. 4A, and the coil 431 may include one or more windings. For example, the planar coil may be a spiral planar coil with a first end positioned near the center of the spiral and a second end positioned at the outside edge of the planar spiral. In some embodiments, the coil 431 may be an assembly of one or more stacked layers of planar coils. The coil 431 may also be in the form of any suitable geometry to generate a magnetic field 440 able to be modulated by the changing gap G1 and detected by the first and second sensor elements 450a, 450b. For example, the coil 431 may be a wire wound around a bobbin coupled to the base 410.

In some embodiments, the coil 431 is disposed within the base 410 as shown in FIG. 4A. In other embodiments, the coil 431 is disposed on or above the second side 412. The coil 431 may also located in the same plane as the first and second sensor elements 450a, 450b, such as the planar coil 431 being disposed on the first side 411 between the sensor elements 450a, 450b.

At least during operation, the electromagnet 430 generates the magnetic field 440 shown as arrows that extends across the membrane 206 into the second region 208, and may even pass through the carrier 130. The magnetic field 440 extends from opposing lateral sides of the electromagnet 430. The magnetic field 440 extending from one lateral side of the electromagnet 430 circulates in an opposite direction from the field extending from the other lateral side of the electromagnet 430. This magnetic field 440 includes a first and second usable field portion 441a, 441b on opposing lateral sides of the electromagnet 430 as shown by the arrows in FIG. 4A. The first and second usable field portions 441a, 441b circulate in opposing directions and have the same or roughly the same field strength. The first and second usable field portion 441a, 441b pass through the first and second sensor elements 450a, 450b, respectively, above the membrane 206 and pass through the first sensor element 450a and second sensor element 450b in at least one opposing direction, such as at least a portion of first and second usable field portions 441a, 441b passing through the first and second sensor elements 450a, 450b in the +X-direction and −X-directions, respectively.

In some embodiments, the thickness of the base 410 is selected such that the first and second useable field portions 441a, 441b generated by the electromagnet 430 pass through the first and second sensor elements 450a, 450b, respectively. In some embodiments, the base 410 may be a PCB with a spacer material disposed between the electromagnet 430 and the second side 412 to increase the distance between the electromagnet 430 and the first and second sensor elements 450a, 450b.

The first and second sensor elements 450a, 450b are magnetic field sensor elements configured to measure the magnetic flux density. Changes in the magnetic flux density are used to determine the position of the carrier 130. For example, the first and second sensor elements 450a, 450b may be configured to convert the magnetic flux density into a voltage signal that is sent to the controller 150. The voltage signal may be correlated to the dimension of the gap G1.

While the first and second sensor elements 450a, 450b are shown disposed on the first side 411, the sensor elements 450a, 450b may be disposed on the second side 412 or embedded in the body 410. In some embodiments, the sensor 400 is disposed in second region 208 rather than in first region 207. The base 410 may be a barrier between the second region 208 and another region of the station 205 at an atmospheric pressure. Thus, the first side 411 may experience vacuum conditions while the second side 412 is exposed to atmospheric conditions. The first side 411 may be the datum, similarly to the underside 211 of the membrane 206, to measure the gap G1. In some embodiments, the membrane 206 is omitted but the base 410 is configured to be a barrier between the second region 208 and another region of the station 205 that is at a different pressure, such as atmospheric pressure. The first side 411 may be the datum, similarly to the underside 211 of the membrane 206, to measure the gap G1.

The linear stator 230 generates a magnetic field to levitate and/or drive the carrier 130. Part of this generated magnetic field will become a stray field that interacts with the sensor 400. The horizontal component of the stray field from the linear stator 230 (not shown) positioned on the right side of the sensor 400, shown by arrow labeled F, is weaker than the vertical component of the stray field generated by the linear stator 230. The horizontal component of the stray field F is weaker than the vertical component because, at least in part, the coils (not shown) of the linear stator 230 are substantially vertically wound. In some embodiments, and as shown in FIG. 4A, the first and second sensor elements 450a, 450b are oriented to measure the magnetic flux density in the horizontal direction (e.g., in the horizontal plane of the X, Y axis). In other words, the first and second sensor elements 450a, 450b may be used to detect the horizontal component of a magnetic flux density vector, such as the x-component of the generated magnetic fields. Without being bound by theory, orienting the sensor elements 450a, 450b to measure the magnetic flux density in the horizontal direction minimizes or eliminates the effect of the vertical component of the stray field on the sensor elements 450a, 450b. The first and second sensor elements 450a, 450b may be a GMR element or a TMR element. In some embodiments, there is a clearance 271 between the sensor elements 450a, 450b and the membrane 206 such that the membrane 206 is not in contact with the sensor elements 450a, 450b.

Additionally, the first and second sensor elements 450a, 450b are separated by a distance D1, such being 10 mm apart or less than 10 mm apart, such as 9 mm apart, such as 8 mm apart, such as 7 mm apart, such as 6 mm apart, such as 5 mm apart, such as 4 mm apart, such as 3 mm apart, such as 2 mm apart, such as 1 mm apart. This distance is small enough that the horizontal stray field F experienced by both the first and second sensor elements 450a, 450b is roughly the same or is at least at a constant ratio between the two sensor elements 450a, 450b. This allows the controller 150 to compensate for the effect of the horizontal stray field F since the sensor elements 450a, 450b experience the horizontal stray field F in the same direction and experience respective useable field portions 441a, 441b that are circulating in opposing directions.

For example, the horizontal component of the magnetic flux density detected by the first sensor element 450a is B₁ and the horizontal component of the magnetic flux density detected by the second magnet field sensor element 450b is B₂. The first sensor element 450a experiences the horizontal component of the flux density of the magnetic stray field F (B_{stray}) and the horizontal component of the flux density of the first useable field portion 441a (B_{Useable}) generated by the electromagnet 430. The second sensor element 450b experiences the horizontal component of the flux density of the magnetic stray magnetic field F (B_{stray}) and the horizontal component of the flux density of the second useable field portion 441b (B_{Useable}) which is the same as the first useable field portion 441a but in an opposite direction. The horizontal component of the usable field portions 441a, 441b are shown as x-component 491 of vector 490 in FIGS. 4A x-component 491a of vector 490a in FIG. 4B. The stray field F generated by the adjacently positioned linear stator 230 is substantially in the same direction for each sensor element 450a, 450b and is assumed to have the same flux density based on the positioning of the two sensor elements 450a, 450b. Based on a system of equations, the controller can determine a difference in the magnetic flux density (B₁−B₂) detected by the first and second sensor elements 450a, 450b that can be correlated to a size of the gap G1:

$${B}_{1} = {B}_{stray} + {B}_{Useable}$$

$${B}_{2} = {B}_{stray} - {B}_{Useable}$$

$${B}_{1} - {B}_{2} = 2 ( {B}_{Useable} )$$

FIG. 4A shows the carrier 130 in a first position in the Z-direction close to the membrane 206. FIG. 4B shows the carrier 130 in a second position in the Z-direction, having moved in the negative Z-direction, such that the carrier 130 is farther away from the membrane 206. Thus, the gap G1 in FIG. 4A is smaller than the gap G1 in FIG. 4B. The sensor elements 450a, 450b are configured to sense the x-component of a magnetic flux density vector. In other words, the sensing direction of the sensor elements 450a, 450b is in the x-direction. As will be explained below, each sensor element 450a, 450b will sense the x-component that extends in opposing direction, such as the sensor element 450a sensing an x-component extending in the positive x-direction and sensor element 450b sensing an x-component extending in a negative x-direction. The electromagnet 430 is vertically orientated, and the poles extend in a vertical direction (e.g., extend in the z-direction) that is perpendicular to the sensing direction (e.g., x-direction) of the sensor elements 450a, 450b.

FIG. 4A shows the vector 490 of the magnetic flux density of the useable field 441a, 441b passing through the sensor elements 450a, 450b, respectively. The vector 490 has an x-component 491 that is measured by the magnetic sensor 450a, 450b. The z-component of the vector 490 is not shown. As shown in FIG. 4A, the x-component 491 experienced by the first sensor element 450a extends in a first direction (e.g., positive x-direction) and the x-component 491 experienced by the second sensor element 450b extends in a second direction (e.g., negative x-direction) that is opposite of the first direction.

FIG. 4B shows the change in the vector (now shown as vector 490a) of the magnetic flux density after the carrier 130 is moved to the second position to increase the size of the gap G1. The x-component of the magnetic flux density vector increased as the size of the gap G1 increased while the magnitude of the magnetic flux density decreased as the gap G1 increased.

As shown in FIGS. 4A and 4B, the change in the size of the gap G1 modulates the detected magnetic flux density. FIG. 4B shows that the vector 490a has decreased in magnitude due to the increase in the size of the gap G1. The vector 490a shown in FIG. 4B has an x-component 491a that is larger than the x-component 491 of vector 490 shown in FIG. 4A due to the change in the size of the gap G1.

In some embodiments, the sensor elements 450a,b are configured to detect the x-component of the magnetic flux density vector. The sensor 400 may output a voltage signal based on the differences in the x-component of magnetic flux density vector detected by the sensor elements 450a,b. This voltage signal may then be correlated to a size of the gap.

The voltage signal produced by the sensor elements 450a,b is proportional to the detected magnetic flux density. Thus, the controller 150 may use the voltage signal to calculate the magnetic flux density detected by the sensor 400.

In some embodiments, the voltage signal produced by the sensor 400 does not have a linear relationship to the size of the gap G1. In other words, a unit increase in the voltage does not indicate the same unit increase in the size of the gap G1. Therefore, the voltage signal is linearized to determine the size of the gap G1 detected by the sensor 400.

The controller 150 may have a lookup table stored in the memory to linearize the voltage signal. The lookup table includes one or more inputs that are each indexed to an output. In some embodiments, each input corresponds to a voltage. The output is a size of the gap G1 that corresponds to the voltage. The controller 150 inputs the voltage of the voltage signal to output the size of the gap G1. In some embodiments, the current, such as the amplitude of the current, is the output of the sensor 400 that is input into the lookup table to output a size of the gap G1.

The sensor 400 may be calibrated to compensate for differences in the components of the sensor 400, such as variations in the sensitivity of the components or for variations in the position of the components. For example, each sensor element 450a,b may output different voltage signals for the same experienced x-component of a magnetic flux density vector. As another example, the first sensor element 450a may be closer to the membrane 206 than the second sensor element 450b. Thus, the voltage signal output of one or both of the magnetic sensor elements 450a, 450b may be inaccurate. The sensor 400 may be calibrated to account for the inaccuracy in the signal produced by each sensor element 450a, 450b. The controller 150 or processor of the sensor 400 may adjust the voltage signal output by one or both of the sensor elements 450a,b by a factor to correct for the error. In some embodiments, the sensor 400 is calibrated by supplying a known current to the coil 431 and registering the voltage output by the sensor elements 450a,b and adjusting the voltage output by a factor accordingly.

In some embodiments, the sensor 400 is calibrated prior to determining the size of the gap G1. In other words, the determining the size of the gap G1 requires first calibrating the sensor 400 and then comparing the voltage signal to the associated output value of the lookup table. This calibration may include accounting for the differences in the sensitivity and position of components of the sensor 400 as well as for the position of the underside 211 of the membrane 206. For example, the raw voltage signal output by the sensor elements 450a, 450b is calibrated prior to inputting the voltage signal into the lookup table. Thus, the calibrated voltage may be the input of the lookup table that is associated an output that corresponds with the size of the gap G1. The sensor 400 may be calibrated prior to placing the sensor 400 in the first region 207, after placing the sensor 400 in the first region 207, or even in between operations of the process station 205.

In some embodiments, the sensor 400 has sensor elements 450a, 450b configured to sense magnetic flux density in the vertical direction (e.g., Z-direction) by aligning the sensor 400 in a vertical orientation, versus the horizontal orientation shown in FIG. 4A. In this configuration the first and second sensor elements 450a, 450b are spaced apart in the vertical direction and the magnetic axis 439 of the electromagnet 430 is aligned in the horizontal direction. In this configuration, the sensor 400 compensates for the stray field generated by the linear stator 230 in the vertical direction rather than the stray field in the horizontal direction F, which can alternately be useful to measure the gap G1. The first and second sensor elements 450a, 450b are positioned close enough together such that the vertical stray field is in the same direction and is also roughly the same strength or at least has a strength that differs at a constant ratio. This allows the controller 150 to compensate for the vertical stray field, similarly to the horizontal stray field, to detect a differential between the magnetic flux density sensed by the first and second sensor element 450a, 450b.

FIGS. 5A illustrates partial cross-section of the process station 205 that show a schematic side view of a magnetic sensor 500. The magnetic sensor 500 may be included within the sensor 270 to detect the gap G1 between the carrier 130 and the membrane 206. The magnetic sensor 500 has similar components as the magnetic sensor 400 as indicated by the reference signs without reciting the description of these components of the magnetic sensor 400 for brevity. The magnetic sensor 500 may operate similarly to magnetic sensor 400 described above. The carrier 130 is shown in a position underneath the membrane 206 similar to the position shown in FIG. 4A.

The electromagnet 430 of magnetic sensor 500 shown in FIG. 5A includes a constant alternating current (AC) source 535 rather than the constant DC current source 435 shown in FIG. 4A. The electromagnetic field 440 is generated by the coil 431 when the AC constant current source 535 supplies the current to the coil 431. The AC constant current source 535 may selectively supply current to the coil 431 to generate the magnetic field 440. The AC constant current source 535 facilitates the generation of an alternating magnetic field 440 with a consistent strength. For example, the switch 436 may be coupled to the coil 431 and to the AC constant current source 535. The controller 150 may open (e.g., switch off) the switch 436 to stop the current flow from AC constant current source 535 to the coil 431 to stop the generating of the magnetic field 440 and close (e.g., switch on) the switch 436 to complete the circuit to cause the generation of the magnetic field 440.

The voltage signal produced by the sensor elements 450a,b is proportional to the detected magnetic flux density. Thus, the controller 150 may use the voltage signal to calculate the magnetic flux density detected by the sensor 500. FIG. 5B illustrates a graph 550 illustrating an alternating current 551 supplied by the AC constant current source 535 to the coil 431 over time. FIG. 5C illustrates a graph 560 of a voltage signal 561 output by the magnetic sensor 500 over the same time frame. As shown, the voltage signal 561 is sinusoidal similarly to the sinusoidal wave form of the alternating current 551. The peak-to-peak voltage 562 of the voltage signal 561 can be detected, such as being detected by use of the first and second sensor elements 450a, 450b and the controller 150. This peak-to-peak voltage 562 can be correlated with the size of the gap G1.

In some embodiments, the voltage signal 561 may be analyzed to separate noise sources from the sensor reading, such by analyzing the voltage signal 561 using principles like phase-synchronous-rectification, Lock-In-Amplification or even Heterodyne amplification. Additionally systematic error and the stator 230 current amplitude can cancel out from the sensor reading by subtracting a constant factor from the sensor reading.

In some embodiments, the peak-to-peak voltage 562 of the voltage signal produced by the sensor 500 does not have a linear relationship to the size of the gap G1. In other words, a unit increase in the voltage does not indicate the same unit increase in the size of the gap G1. Therefore, the value of the peak-to-peak voltage 562 is linearized to determine the size of the gap G1 detected by the sensor 500. For example, the controller 150 may have a lookup table stored in the memory to linearize the peak-to-peak voltage 562, which can include a function that correlates the measured peak-to-peak voltage versus the gap distance G1. The lookup table includes a plurality of inputs that are each indexed to an output. Each input corresponds to a peak-to-peak voltage 562. The output is a size of the gap G1 that corresponds to the peak-to-peak voltage 562. The controller 150 inputs the extracted peak-to-peak voltage 562 of the voltage signal 561 to output the size of the gap G1. In some embodiments, the lookup table may use a non-linear function, with the extracted peak-to-peak voltage 562 input into the non-linear function to output the size of the gap G1.

The sensor 500 may be also be calibrated to compensate for differences in the components of the sensor 500 similarly to what is described above for sensor 400. In some embodiments, the sensor 500 is calibrated prior to determining the size of the gap G1. In other words, the determining the size of the gap G1 requires first calibrating the sensor 500 and then comparing the peak-to-peak voltage 562 of the voltage signal 561 to the associated output value of the lookup table. For example, the raw voltage signal output by the sensor elements 450a, 450b is calibrated prior to inputting the voltage signal into the lookup table. Thus, the peak-to-peak to-peak voltage 562 may be extracted from the calibrated voltage and input into the lookup table to output the gap G1.

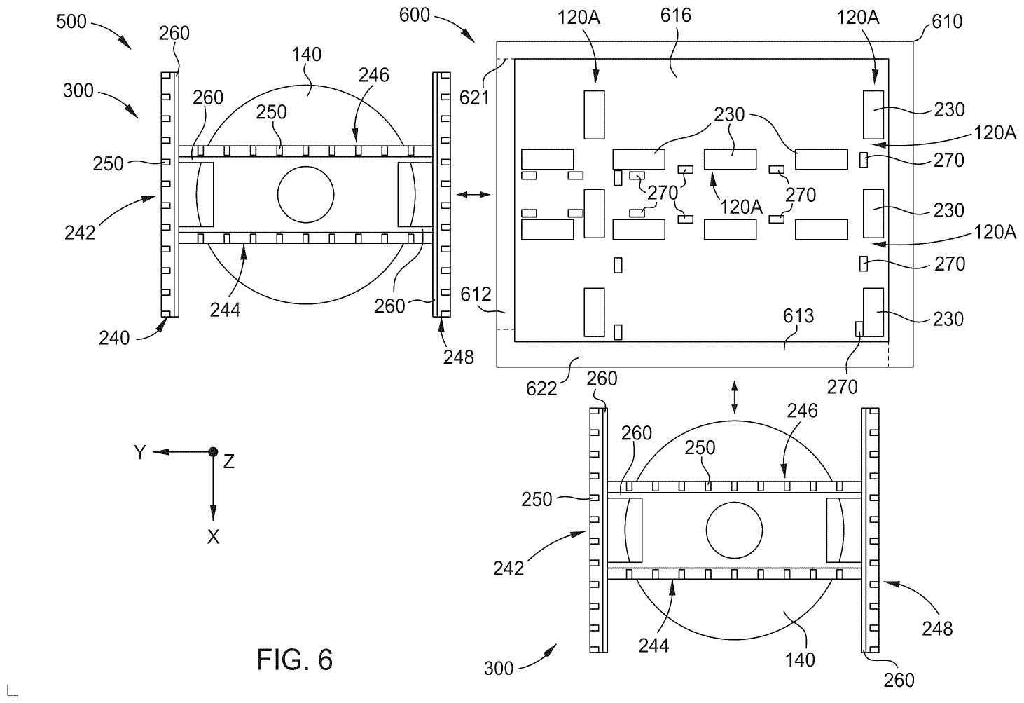

FIG. 6 illustrates a top view of a system 600 that includes the example carrier 300 of FIG. 3 and an exemplary routing station 610, in accordance with embodiments of the present disclosure. The routing station 610 may be the fourth station 114, the fifth station 115, or the eighth station 118 of the substrate processing system 100 shown in FIG. 1. The routing station 610 is configured to change the axial direction of travel of the carrier 300.

The routing station 610 includes two magnetic levitation actuator assemblies 120A disposed in the X-direction and two magnetic levitation actuator assemblies 120A disposed in the Y-direction disposed in a housing 611 above a membrane 616. Each of the magnetic levitation actuator assemblies 120A include a plurality of linear stators (e.g., linear stators 230). For example, each of the magnetic levitation actuator assemblies 120A disposed in the X-direction may include three linear stators 230, and each of the two magnetic levitation actuator assemblies 120A disposed in the Y-direction may each include four linear stators 230, for a total of 14 linear stators 230 in the routing chamber. The magnetic levitation actuator assemblies 120A disposed in the X-direction and Y-direction also include a plurality of sensors 270, which may include magnetic sensor 400 or 500 disclosed herein. As shown, the each magnetic levitation actuator assembly 120A disposed in the X-direction includes three sensors 270 and each magnetic levitation actuator assembly 120A disposed in the Y direction includes five sensors 270.

The membrane 616 isolates a region within the housing 611 in which the magnetic levitation actuator assemblies 120A are disposed with another region of the housing below the membrane 616 in which the carrier 300 is transported through. The membrane 616 may be part of lid assembly for the routing station 610. The membrane 616 may be made from the same material as membrane 206. The housing 611 may include a plurality of side walls. A first port 621 is formed in a first side wall 612 of the housing 611 and a second port 622 is formed in a second side wall 613 of the housing 611. The first and second ports 621, 622 are disposed beneath the membrane 616 to allow the carrier 300 to enter and exit the region of the routing station 610 beneath the membrane 616.

The routing station 610 may be configured to change the axial direction of travel of the carrier 300 so that carrier 300 moves in a linear fashion in a first axial direction (e.g., X-direction) instead of linearly in a second axial direction (e.g., Y-direction), or vice versa. The axial direction of travel of the carrier 300 may be configured to be changed without moving the one or more magnetic levitation actuator assemblies 120A. For example, the routing station 610 may receive the carrier 300 through the first port 621 in the first sidewall 612, and selectively change the direction of axial travel of the carrier 300 to enable the carrier 300 to exit the routing station 610 through the second port 622 in the second sidewall 613. In this manner, the routing station 610 may facilitate the transportation of the carrier 300 from one chamber arranged in a first direction (e.g., the fourth station 114, arranged in the X-direction) to another chamber arranged in a second direction (e.g., the fifth station 115, arranged in the Y-direction), as described above.

Each magnetic levitation actuator assembly 120A disposed in the Y-direction is configured to convey the carrier 300 in the Y direction, with one of the magnetic levitation actuator assemblies 120A being positioned in the housing 611 over the second rail 244 of the carrier 300 and the other magnetic levitation actuator assemblies 120A being disposed over third rail 246 of the carrier 300. Each magnetic levitation actuator assembly 120A disposed in the X-direction is configured to convey the carrier 300 in the X-direction, with one of the magnetic levitation actuator assemblies 120A positioned within the housing 611 over first rail 242 of the carrier 300 and the other magnetic levitation actuator assemblies 120A positioned over fourth rail 248 of the carrier 300.

Stators 230 of the magnetic levitation actuator assemblies 120A disposed in the Y-direction are energized to convey the carrier 300 through the first port 621. One or more of the sensors 270 of the magnetic levitation actuator assemblies 120A disposed in the Y-direction are selectively switched-on to monitor the position of the carrier 300 as the carrier 300 is conveyed in the Y-direction. The stators 230 and sensors 270 of the magnetic levitation actuator assemblies 120A disposed in the X-direction may be turned-off while the carrier 300 is conveyed in the Y-direction.

The magnetic levitation actuator assemblies 120A disposed in the Y-direction moves the carrier 300 in the Y-direction until the first and fourth rails 242, 248 (e.g., rails running in the X-direction) are disposed underneath the magnetic levitation actuator assemblies 120A disposed in the X-direction. The stators 230 of the magnetic levitation actuator assemblies 120A disposed in the X-direction may then be gradually energized to levitate the carrier 300, with the stators 230 of the magnetic levitation actuator assemblies 120A disposed in the Y-direction being gradually turned-off until the carrier 300 is levitated by the stators 230 running in the X-direction. One or more of the sensors 270 of the magnetic levitation actuator assemblies 120A disposed in the X-direction may be turned-on to monitor the position of the carrier 300, with the sensors 270 of the magnetic levitation actuator assemblies 120A disposed in the Y-direction being turned-off. The stators 230 of the magnetic levitation actuator assemblies 120A disposed in the X-direction may then convey the carrier 300 in the X-direction to exit the second port 622.

The controller 150 may use the known position of the carrier 300 within the station to selectively turn-on, turn-off, and/or power down the sensors 270. For example, the controller 150 may turn-off or power down one or more sensors 270 when the controller 150 knows that the carrier 130 is not underneath the sensors. In other words, the controller 150 may turn on one or more of the sensors 270 located in a position above the known position of the carrier 300 to measure the gap G1.

While the foregoing is directed to embodiments of the present disclosure, other and further embodiments of the disclosure may be devised without departing from the basic scope thereof, and the scope thereof is determined by the claims that follow.

What is claimed is:

1. A magnetic sensor, comprising:
a base including a first side and a second side;
a current source;
at least one coil coupled to the base and coupled to the current source, wherein a magnetic flux is generated when the current source supplies a current to the at least one coil; and
a first sensor element and a second sensor element coupled to the base, wherein the first sensor element and second sensor element are configured to measure magnetic flux density, and the generated magnetic flux is configured to pass through the first sensor element in a first direction and pass through the second sensor element in a second direction that is opposite to the first direction.

2. The magnetic sensor of claim 1, wherein the base is a printed circuit board.

3. The magnetic sensor of claim 2, wherein the at least one coil is disposed on one or more layers of the printed circuit board.

4. The magnetic sensor of claim 1, wherein the first and second sensor elements are at least one of a Hall Effect element, Giant magnetoresistance (GMR) element, or a Tunnel magnetoresistance (TMR) element.

5. The magnetic sensor of claim 1, wherein the at least one coil is disposed in the base.

6. The magnetic sensor of claim 1, wherein the current source is a constant direct current source.

7. The magnetic sensor of claim 1, wherein the current source is an alternating current source.

8. The magnetic sensor of claim 7, wherein an alternating current supplied by the alternating current source is between about 1 kHz and about 3 kHz.

9. The magnetic sensor of claim 8, wherein the alternating current supplied by the alternating current source is between about 1 kHz and about 3 kHz.

10. The magnetic sensor of claim 1, wherein the first sensor element and the second sensor element disposed over the second side.

11. The magnetic sensor of claim 1, wherein the current supplied to the at least one coil is adjustable based on feedback from the magnetic flux density measured by the first sensor element and second sensor element.

12. The magnetic sensor of claim 1, wherein the first sensor element and second sensor element are embedded in the base.

13. A magnetic levitation actuator assembly, comprising:
a linear stator;
a magnetic sensor positioned adjacent to the linear stator, wherein the magnetic sensor comprises:
a base;
an electromagnet including at least one coil configured to generate a magnetic flux, the at least one coil coupled to the base; and
a first sensor element and a second sensor element coupled to the base, wherein:
the first sensor element and second sensor element are configured to measure magnetic flux density, and
the magnetic flux generated by the at least one electromagnet is configured to pass through the first sensor element in a first direction and pass through the second sensor element in a second direction that is opposite to the first direction.

14. The magnetic levitation actuator assembly of claim 13, wherein the electromagnet further comprises a direct current source coupled to the at least one coil configured to supply a current to the coil to generate the magnetic flux.

15. The magnetic levitation actuator assembly of claim 13, wherein the electromagnet has a magnetic axis that is perpendicular to a longitudinal axis of the base, wherein the at least one coil is disposed between the first sensor element and the second sensor element.

16. The magnetic levitation actuator assembly of claim 13, wherein the electromagnet further comprises an alternating current source coupled to the at least one coil configured to supply an alternating current to the coil to generate the magnetic flux.

17. The magnetic levitation actuator assembly of claim 16, wherein the alternating current supplied by the alternating current source is between about 1 kHz and about 3 kHz.

18. The magnetic levitation actuator assembly of claim 16, wherein the alternating current supplied by the alternating current source is between 1 kHz and 20 KHz.

19. The magnetic levitation actuator assembly of claim 13, wherein the first sensor element and second sensor element are embedded in the base.

20. The magnetic levitation actuator assembly of claim 13, further comprising a current source, wherein a current supplied to the at least one coil by the current source is adjustable based on feedback from the magnetic flux density measured by the first sensor element and second sensor element.
